(19) United States
(12) Patent Application Publication
(10) Pub. No.: US 2012/0182607 A1
(43) Pub. Date: Jul. 19, 2012

(54) CONCENTRATOR FOR SOLAR ENERGY GENERATION AND PRODUCTION THEREOF FROM POLYMERIC MATERIALS

(75) Inventors: Uwe Numrich, Gross-Zimmern (DE); Thomas Arndt, Luetzelbach (DE); Werner Arnold, Schaafheim (DE); Michael Olbrich, Karlstein (DE)

(73) Assignee: Evonik Degussa GmbH, Essen (DE)

(21) Appl. No.: 13/498,793

(22) PCT Filed: Sep. 7, 2010
(86) PCT No.: PCT/EP2010/063065

§ 371 Date: Mar. 28, 2012

(30) Foreign Application Priority Data
Oct. 12, 2009 (DE) 10 2009 045 582.5

(51) Int. Cl. F21V 13/08; B29D 11/00; F24J 2/10; H01L 31/0232; B82Y 20/00

(52) U.S. Cl. 359/360; 126/684; 136/259; 264/1.9; 977/902

(57) ABSTRACT

The present invention relates to a concentrator for concentrating solar radiation and to the production thereof from polymeric materials. The concentrator according to the invention can be used in photovoltaically or in particular in solar thermally usable systems. The concentrator according to the invention allows for the efficient concentration of solar radiation onto objects such as solar cells, independent of the geometry thereof. This relates, for example, to the surface of a solar cell as it is used in concentrating photovoltaics, and also an absorber tube as it is used in concentrating solar heating, for example in the scope of the parabolic trough technology.

### FIELD OF THE INVENTION

The present invention relates to a concentrator for concentrating solar radiation and to the production thereof from polymeric materials. The inventive concentrator can be employed in photovoltaic systems, or more particularly in solar thermal energy systems.

The inventive concentrator enables the efficient concentration of solar radiation onto objects such as solar cells or absorber units, irrespective of the geometry thereof. This relates, for example, to the area of a high-performance solar cell as used in concentrated photovoltaics, and equally to an absorber tube which is used in concentrated solar thermal energy systems, for example in the context of parabolic trough technology.

### STATE OF THE ART

In the utilization of solar radiation, a distinction is usually drawn between point- and line-concentrating technologies. The line-concentrating technologies include parabolic trough technology, which is used in concentrating solar thermal energy systems, and which concentrates the incident radiation onto an absorber tube in the form of a line by means of a parabolically curved reflecting surface (parabolic mirror).

Parabolic trough concentrators are currently being used in solar thermal power plants which are designed for outputs of, for example, up to 300 MW. The absorber tube is usually surrounded here by an evacuated glass tube. The reflector or concentrator used is normally inorganic solar glass. In addition, polymer-based mirror films in which a polymer film has been applied to an aluminium plate, aluminium-based composite systems or another backing material are used. What is common to all these systems is that a complex forming step has to be carried out at very high process temperatures to obtain the necessary parabolic geometry. This is particularly complex in the case of solar mirrors based on inorganic glass, which is generally used with a thickness of approx. 4 to 6 mm. The thermoforming takes place at temperatures of approx. 600° C., and has to be carried out before the metallization. This is a costly and inconvenient process. In a further process step, the actual metal mirror is applied to this backing system. This metal mirror generally consists of a silver layer with a metallic anticorrosive finish on the reverse side and a protective paint system consisting of 3 layers on the reverse side. Owing to the three-dimensional geometry of the parabolic mirror, this is likewise a very inconvenient and complex process step.

Furthermore, the logistics, for example in relation to transport and mounting of these three-dimensional mirrors with dimensions of, for example, approx. 1.6*1.7 m, constitutes a considerable challenge. This gives rise to a further disadvantage of inorganic solar glass systems: they are extremely prone to breakage, which is a problem especially during mounting, cleaning and maintenance. Furthermore, the systems are susceptible to extreme weathering influences, such as storms or hail. Fragments of the solar glass mirrors which form lead in the extreme case even to marked secondary damage to absorber tubes and to neighbouring glass mirror units. An additional factor which cannot be neglected is the resulting critical occupational safety when working with such systems. A further disadvantage of established systems is the high weight. To mount these comparatively heavy solar glass mirrors, a costly substructure and costly concrete foundations are needed.

Solar mirrors based on inorganic glass have become established as the dominant reflector technology to date in spite of the disadvantages described, in particular in concentrating solar thermal energy systems.

Systems based on aluminium composites do not have the necessary solar reflection, and are therefore suitable only to a limited degree for use in solar power plants. A certain market share is possessed by these reflector systems in small- or medium-scale systems, for example owing to their weight advantage in roof mounting. These are employed for generation, for example, of process refrigeration for the purpose of operating air conditioning systems.

Polymeric mirror films, primarily adhesive-bonded to aluminium sheets, have to date not become established on the market. One disadvantage is considered to be, for example, the complex and quality-critical lamination onto the preshaped backing material. In addition, some of the polymeric mirror films available have defects with regard to long life and adhesive bonding.

EP 1 771 687 details protection of the mirror layer also with acrylic glass, without any more precise specification of this technology.

Some designs of mirror film systems are presented hereinafter.

US 2008/0093753 discloses a process for producing mirror films. The protective film at the same time constitutes the backing film, which is converted to the final form as early as in the course of production and is then metallated. The metal coating is in turn provided with an indeterminate protective layer on the reverse side. There is no further detail about the film structure or the reflector construction.

In U.S. Pat. No. 4,645,714, protective films for parabolic mirrors composed of two separate (meth)acrylate-based coatings are applied. The outer coating contains a UV absorber, and the inner coating, directly adjoining the silver layer, an inhibitor. By virtue of this structure, the inner layer is protected by the outer layer. The silver layer in turn was applied beforehand by vapour deposition to a two-layer polyester laminate produced by coextrusion. The system is very complex to produce overall and exhibits high susceptibility to mechanical stress.

In order to avoid this problem, in U.S. Pat. No. 5,118,540, an abrasion-resistant and moisture-resistant film based on fluorocarbon polymers is applied by adhesive bonding. Both the UV absorption reagent and the corrosion inhibitor are part of the adhesive layer, with which the film is bonded to the metal surface of the polyester backing film which has been subjected to vapour deposition. In this case, the adhesive layer may in turn, analogously to the (meth)acrylate double coating detailed above, consist of two different layers, in order to separate corrosion inhibitor and UV absorption reagent from one another.

WO 2007/076282 details an alternative structure for better protection of the silver coating. A PET backing film is subjected to vapour deposition of silver on the side facing away from the light, and provided on the other side with a poly(meth)acrylate-based (UV) protective film. The reverse side of the vapour-deposited silver can be provided either directly with a pressure-sensitive adhesive (PSA) or, to improve the corrosion resistance on the reverse side and for better adhesion of the PSA, subjected to vapour deposition of an additional copper layer. The teaching that a long-life UV-protective finish is required is not taken into account in WO 2007/076282. In addition, such systems can be processed only with difficulty and are susceptible to mechanical stress.

The prior art UV protective films have the disadvantage that benzotriazoles are used as UV absorbers. These have only a comparatively short intrinsic stability under the influence of UV radiation and are therefore not effective UV protection for an adhesive layer or a backing film based, for example, on polyester.

Mirror film systems, however, have the disadvantage that the adhesive operation is intrinsically susceptible to faults, and that, for example, the parabolic trough of a parabolic trough collector has to be produced in a separate process and the mirror film subsequently has to be laminated on in a complex and quality-critical process step. The same also applies to other concepts using concentrators for solar power generation.

In WO 00/22462, a flexible concentrator is tensioned on the reverse side and converted flexibly to the desired form. The concentrator consists, from the outside inward, of an acrylic protective layer, the metal layer, an optional damping layer consisting of a foam and a backing. All layers are bonded to one another with an adhesive layer.

### Problem

The object of the present invention was to provide a novel concentrator for concentration of solar radiation, which enables particularly simple mounting. The inventive concentrator can be used in systems with photovoltaic uses or more particularly solar thermal energy uses. Furthermore, this concentrator should have at least equivalent properties compared to the prior art.

More particularly, the concentrator should have lower susceptibility to breakage compared to the prior art and hence also a reduced risk of secondary damage. In addition, the concentrator should have a lower intrinsic weight, and enable the possibility of a less costly subconstruction. At the same time, the concentrator must naturally have a long life of at least 20 years, a high reflection performance for solar radiation and an improved or at least equivalent stability to environmental influences compared to the prior art.

It was a further object of the present invention to provide a very simple production process which, compared to the prior art, can be performed in a less expensive, more energy-efficient, simple and rapid manner, and demands less complex logistics.

Further objects which are not stated explicitly are evident from the overall context of the description, claims and examples which follow.

### Solution

The object is achieved by a novel process for producing self-supporting concentrators and the provision of such self-supporting concentrators for systems for solar power generation.

Surprisingly, the necessary performance criteria are established in concentrators for systems for solar power generation, avoiding the described disadvantages of existing concentrator designs, by means of a novel concentrator composition based on a self-supporting polymeric structure which is described in detail hereinafter.

More particularly, the stress criteria are satisfied by adjusting the required total thickness and flexibility of the laminate to be produced. In the adjustment of composition and thickness of the polymer layer facing the solar radiation, however, the reflection performance should also be considered.

The terms “polymer layer” and “backing layer” herein-after include plates, films, coating systems or coatings based on polymers. Such a layer may in principle have a thickness between 1 μm and 2 cm.

The term “metal layer” in contrast refers to layers composed of pure metal or alloys. The thicknesses of these metal layers are independent of the other layers detailed below in the text.

In this document, the term “self-supporting” means that a workpiece, in contrast to a mirror film, after the curving or forming step, retains this form at use temperatures up to at least 50° C., preferably at least 65° C., and the ambient environmental conditions, for example wind speeds. In connection with parabolic trough collectors, this means, for example, that a parabolic geometry, once shaped, is maintained in the course of transport, installation and operation of the system.

The terms “reflector” and “concentrator” are used synonymously in the context of this document.

The object is achieved more particularly by provision of a novel process for producing a self-supporting concentrator for systems for solar power generation and by this concentrator produced by the process according to the invention. The process according to the invention consists of at least the following steps:
a first polymer layer is coated with a silver mirror layer structure by physical vapour deposition,
on the other side of the silver mirror layer structure is applied a second polymer layer,
the laminate thus produced is converted to a use form, for example a parabolic trough, by means of simple forming processes, preferably by means of cold curving,
the shaped, preferably parabolic, laminate is installed as concentrator into a system for solar power generation,
the polymer layer facing the light source is highly transparent.

In addition, the concentrator obtained from the process is self-supporting.

In one embodiment of the process, the first polymer layer is provided with a highly transparent primer layer on the side to be coated with a metal in the first step of physical vapour deposition. In the case that the first polymer layer is the highly transparent polymer layer, and hence the polymer layer facing the light in the end application, it is provided with a highly transparent primer layer on the side to be coated with a metal mirror in the first step of the physical vapour deposition.

Optionally, but preferably, the side of the metal layer facing away from the highly transparent polymer layer is then provided with a metallic anticorrosion layer, preferably consisting of copper or an alloy composed of chromium and nickel. This process leads to what are known as back-surface mirrors.

In an alternative process, the backing layer which later faces away from the light source is coated with the metal—or with two successive metals—by means of physical vapour deposition and then the other side of the metal layer is coated with, optionally, a primer and a highly transparent polymer. This process leads to what are known as front-surface mirrors.

In general, the backing layer determines the stiffness and hence is crucial for the shape. In another embodiment it is, however, also possible that the difference in the layer thicknesses between backing layer and highly transparent polymer layer is low and both layers contribute to shaping.

The inventive concentrator may have a total thickness between 1 mm and 2 cm, preferably between 2 mm and 1.5 cm and more preferably between 3 mm and 10 mm.

The highly transparent polymer is preferably polycarbonate, polystyrene, a styrene copolymer, a fluoropolymer or PMMA, preferably PMMA or a fluoro-polymer, the fluoropolymer being, for example, poly-vinylidene fluoride (PVDF). The highly transparent layer is preferably equipped with additives such as inhibitors and/or UV stabilizers.

In a particular embodiment, the highly transparent polymer layer consists of various different polymer layers, which preferably comprise at least one PMMA layer. In this case, the individual additives are distributed homogeneously and/or separately from one another between one or more of these layers.

Optionally, the surface of the highly transparent polymer layer is additionally equipped with a scratch-resistant and/or antisoil coating.

The polymer of the backing layer is preferably poly-carbonate, polystyrene, a styrene copolymer, a polyester or PMMA, more preferably PMMA.

In addition, adhesive layers may optionally be present between each of the individual layers.

As a surprising aspect of the present process, it has been found that the laminate has such a stiffness that it is self-supporting, and that the laminate is simultaneously readily cold-formable, and can thus be converted to the final form by cold shaping—without heating. According to the invention, this property is achieved by virtue of the individual layers, especially the two polymer layers, being matched to one another with regard to stiffness, thickness and other material properties. This gives rise to the great advantage of the process according to the invention, cold shapability into complicated forms such as parabolic forms. In addition, it is possible to ensure this while maintaining an exceptionally smooth surface. This is required, for example, for parabolic trough concentrators.

Furthermore, the production of the laminates from novel polymeric backing and finishing materials makes possible the utilization of new geometric possibilities and the configuration of very (cost-)efficient concentrator and collector geometries.

More particularly, metallization in the two-dimensional state and subsequent forming is now possible. This too is associated with an additional, distinct cost saving.

A further advantage which arises therefrom is that of savings compared to an energy-intensive and costly thermoforming operation with avoidance of high process temperatures.

In a preferred embodiment, in accordance with the invention, a concentrator—viewed from the light source—consisting of at least the following layers is obtained:
a polymer layer comprising UV stabilizer and inhibitors, and comprising PMMA,
a silver mirror layer structure with a thickness between 80 and 200 nm,
a backing layer, preferably consisting of PMMA,
   with the additional feature that the concentrator has been converted to the final form by means of cold forming.

In a preferred embodiment, a concentrator—viewed from the light source—consisting of the following layers is obtained:
a surface finish with soil-repellent and scratch resistance-improving properties
a polymer layer comprising UV stabilizer and inhibitors, and comprising PMMA
an optional adhesive layer
a primer layer
a silver layer with a thickness between 80 and 130 nm
an anticorrosion layer consisting of copper or nickel-chromium with a thickness between 10 nm and 100 nm, preferably between 20 and 50 nm
an optional adhesive layer
a polymeric backing layer consisting of PMMA.

A further feature is that the polymer layer has been converted to the final form by means of cold forming.

Furthermore, the novel inventive concentrator has the following properties, in combination as an advantage over the prior art, particularly with regard to optical properties: the transparent component of the inventive concentrator is particularly colour-neutral and does not become cloudy under the influence of moisture. The concentrator additionally exhibits outstanding weathering resistance and, in the case of optional finishing with a PVDF surface and/or a scratch-resistant finish, very good chemical resistance, for example toward all commercial cleaning compositions. These aspects too contribute to maintaining solar reflection over a long period. In order to facilitate cleaning, the surface has soil-repellent properties. In addition, the surface is optionally abrasion-resistant and/or scratch-resistant.

### DETAILED DESCRIPTION OF THE INVENTION

The Highly Transparent Polymer Layer

The highly transparent polymer layer is composed of highly transparent polymers. These are preferably polycarbonates, polystyrene, styrene copolymers, fluoro-polymers and/or PMMA. Particular preference is given to PMMA and/or fluoropolymers.

The highly transparent polymer layer may be composed of a polymer or of a blend of different polymers. Alternatively, the highly transparent polymer layer may also be a multilayer system of different polymers. One example is systems composed of polymethyl methacrylate (PMMA) and polyvinylidene fluoride (PVDF) layers.

In general, the highly transparent polymer layer is additized to improve the weathering stability and surface-upgraded to improve the surface properties.

According to the application, the reflection performance of the solar radiation should not go below a certain level. CSP solar power plants using parabolic trough technology require, for example, reflection of at least 93% of the relevant wavelength range of solar radiation from approx. 340 to 2500 nm. Only for medium- or small-scale solar thermal energy plants is a lower reflection performance likewise possible.

In general, the relevant wavelength range of concentrating photovoltaics is approx. 300 to 1800 nm.

Irrespective of the composition, the highly transparent polymer layer has a total thickness in the range from 1 μm to 9 mm, preferably in the range from 10 μm to 5 mm, more preferably in the range from 20 μm to 3 mm.

The thickness of the highly transparent polymer layer is crucial in relation to the reflection performance of solar radiation. It may be a lacquer system, a coating, a film or a sheet, which may have the thicknesses already listed. For optimization of the reflection of solar radiation, a highly transparent polymer layer more preferably has a maximum thickness of 1 mm.

The highly transparent polymer layer for front-surface mirrors can be applied by means of coating or adhesive bonding with an adhesive or the primer.

It is important to maintain the required reflection performance of solar radiation. This can be achieved by means of establishment of a particular maximum layer thickness, optionally combined with a multilayer structure, for example to produce a “reflection enhancement stack”.

The Stabilizer Package (Light Stabilizer)

The ideally used highly transparent polymer layer is equipped with UV protection. Appropriate UV protection for films can be found, for example, in WO 2007/073952 (Evonik Rohm) or in DE 10 2007 029 263 A1.

A particular constituent of the UV protection layer used in accordance with the invention is the UV stabilizer package, which contributes to long life and to the weathering stability of the concentrators.

Ideally, the stabilizer package used in the UV protection layers used in accordance with the invention consists of the following components:
a UV absorber of the benzotriazole type,
a UV absorber of the triazine type,
a UV stabilizer, preferably an HALS compound.

Components A and B can be used as an individual substance or in mixtures. At least one UV absorber component must be present in the highly transparent polymer layer. Component C is necessarily present in the polymer layer used in accordance with the invention.

In the case that the highly transparent polymer layer consists of various different polymer layers, the individual additives may be distributed homogeneously and/or separately from one another between one or more of these layers.

More particularly, the concentrator produced in accordance with the invention is notable for its significantly improved UV stability compared to the prior art and the associated longer lifetime. The inventive material can thus be used in solar concentrators over a very long period of at least 15 years, preferably even at least 20 years, more preferably at least 25 years, at sites with a particularly large number of sun hours and particularly intense solar radiation, for example in the south-western USA or the Sahara.

The wavelength spectrum of solar radiation relevant for “solar thermal energy uses” ranges from 300 nm to 2500 nm. The range below 400 nm, especially below 375 nm, should, however, be filtered out to prolong the lifetime of the concentrator, such that the “effective wavelength range” from 375 nm or from 400 nm to 2500 nm is preserved. The mixture of UV absorbers and UV stabilizers used in accordance with the invention exhibits stable, long-lived UV protection over a broad wavelength spectrum (300 nm-400 nm).

The Surface Coating

The term “surface coating” in the context of this invention is understood as a collective term for coatings which are applied to reduce surface scratching and/or to improve abrasion resistance and/or as an antisoil coating.

To improve the scratch resistance or the abrasion resistance, polysiloxanes, such as CRYSTALCOAT™ MP-100 from SDC Technologies Inc., AS 400-SHP 401 or UVHC3000K, both from Momentive Performance Materials, can be used. These coating formulations are applied, for example, by means of roll-coating, knife-coating or flow-coating to the surface of the highly transparent polymer layer of the concentrator. Examples of further useful coating technologies include PVD (physical vapour deposition; physical gas phase deposition) and CVD plasma (chemical vapour deposition; chemical gas phase deposition).

More precise details of antisoil coatings can be found in the literature or are known to those skilled in the art.

The Silver Mirror Layer Construction

The silver mirror layer construction is composed of one up to several different functional layers producible by physical vapour deposition (PVD). The presence of the actual mirror layer is obligatory. On the side facing away from the solar radiation, it is optionally possible to apply an anticorrosion layer. Between the mirror layer and the polymer layer to be coated by means of PVD, it is optionally possible for a primer to be present. In the case that, for example, the highly transparent polymer layer is coated by means of PVD, the primer is on the side facing the solar radiation. In addition, a “reflection enhancement stack” layer structure can be included in the silver mirror layer structure. This is an optimized multilayer structure of very thin metal oxide layers, the use of which can minimize absorption. The reflection enhancement stack layers are generally formed by PVD.

The word “silver” in silver mirror layer structure does not imply that the mirror metal must indeed be silver, but instead expresses that silver is used in a preferred embodiment.

The silver mirror layer structure consisting of optional primer, mirror layer, optional reflection enhancement stack and optional anticorrosion layer is preferably formed by means of physical vapour deposition.

The silver mirror layer structure generally has a thickness between 80 and 200 nm.

Alternatively, the silver mirror layer structure can also be introduced in the form of a prefabricated “silver mirror film”. This likewise has the above-described layer structure, applied to a polymer film (generally polyester). In the case that this polymer film is incorporated on the side of the solar radiation, it can be considered hereinafter as a constituent of the highly transparent polymer layer.

In the case that this polymer film layer (e.g. polyester) of the silver mirror film is incorporated on the reverse side (the side of the silver mirror structure facing away from the solar radiation), this new layer can be considered to be an additional constituent of the backing layer and may optionally be bonded thereto by a further adhesive layer.

The Primer

The primer acts simultaneously as a migration barrier layer to prevent the migration of silver from the mirror layer into the polymeric substrate or of harmful components from the polymeric substrate into the silver mirror layer.

The materials used here are especially those which prevent migration of the constituents which are harmful to the metal layer, or else constituents of the additives which are capable of migration, out of the highly transparent polymer layer. The primer must naturally have similarly highly transparent properties to the actual polymer layer. Ideally, the primer serves simultaneously to promote adhesion, such that no additional adhesive layers are required to the metal layer and/or to the highly transparent polymer layer. In general, the primer is applied by means of physical vapour deposition in a layer thickness between 1 nm and 20 nm. The selection of the primer arises from the adhesion and surface properties of the metal layer and of the highly transparent polymer layer. The primer may, for example, be a thin metal oxide layer.

The Mirror Layer

The mirror layer consists preferably of silver, gold or aluminium, more preferably of silver. Of all potentially possible metal mirror layers, silver has the highest reflectivity in the relevant wavelength spectrum of solar radiation. Alternative reflection layers of aluminium or gold in particular can optionally be optically upgraded with reflectance enhancement stack layers.

Silver is used with a thickness between 50 and 200 nm, preferably between 70 and 150 nm, more preferably between 80 and 130 nm. At these layer thicknesses, a reflection of usually more than 90% of the solar radiation is firstly ensured, and high process and material costs are avoided at the same time.

The mirror layer is preferably applied using modern thin film technologies, preferably using physical vapour deposition. With such a method, the establishment of very tightly packed, homogeneous layers is possible.

The reverse side of the mirror layer can optionally be coated with a second metal layer as an anticorrosion layer, for example of copper or a nickel-chromium alloy. This serves firstly as protection for the metal mirror layer and secondly for better adhesion of the backing layer or of the pressure-sensitive adhesive layer. Such anticorrosion layers are applied preferably in a layer thickness between 10 nm and 100 nm, more preferably between 20 and 50 nm.

The Backing Layer

The choice of the backing layer, i.e. of the polymer layer facing away from the solar radiation, is determined by the following properties which are absolute requirements: the backing layer must have sufficient stiffness and ideally good adhesion properties with respect to the bonded silver mirror layer structure. In addition, the backing layer, depending on the preparation process of the silver mirror layer structure, must either be coatable using physical vapour deposition or be able to be laminated with a silver mirror film. Furthermore, there should be stability to weathering and environmental influences for at least 20 years. With respect to the silver mirror layer, there should also be no loss of adhesion over a long period. Furthermore, the backing layer serves to prevent damage to the anticorrosion layer. However, there is no demand for reflection performance.

Polymers suitable for use in the backing layer have been found to be all polymers which are suitable for production of a sheet with a thickness of at least 0.8 mm. Examples are polyester, polycarbonates, styrene copolymers, polystyrene and PMMA.

In the case of the front-surface mirror, the silver mirror layer structure is formed proceeding from the backing layer by physical vapour deposition.

In the case of the back-surface mirror, the backing layer is applied to the rest of the layer structure by means of adhesive bonding or coating.

The required layer thicknesses of the backing layer are between 0.8 and 19 mm, preferably between 2 and 8 mm. Such layers are generally produced by extrusion, casting or another shaping process, without restricting the invention in any form by the production process.

In general, the backing layer is the shaping and hence principally self-supporting layer of the concentrators produced in accordance with the invention.

The Adhesive Layers

Optionally, adhesive layers may be present between each of the individual layers. More precisely, adhesive layers may be present between backing layer and anti-corrosion layer, between silver mirror layer structure and highly transparent polymer layer and between the individual layers of a multilayer polymer layer.

The adhesive systems used for this purpose are determined, in terms of their composition, from the adhesion properties of the two layers to be adhesive-bonded to one another. In addition, the adhesive systems should contribute to long-life performance, and prevent adverse interactions of the adjacent layers.

Under some circumstances, the optical properties are also of great significance. Adhesive layers which are used on the side of the metal layer facing the solar radiation must be highly transparent. Suitable examples are especially acrylate adhesives.

Use

The concentrators produced in accordance with the invention are preferably used as parabolic trough concentrators of a parabolic trough collector. For this purpose, it is particularly advantageous, as implemented in the process according to the invention, when the concentrator is cold formed or can be shaped cold into the parabolic geometry of the parabolic trough. Thus, it is also possible to produce slightly curved forms, or to adjust the concentrator to only slightly shaped, otherwise two-dimensional collector structures. Examples of end applications with these prerequisites are use in Fresnel mirror collectors, heliostat reflectors as employed in solar tower technology, or in solar dish reflector units.

Efficient thermal forming with avoidance of high temperatures is used, for example, in the case of curving into a paraboloid structure, as frequently used in concentrated photovoltaics (CPVs), or in extremely curved forms for concentrator constructions in medium- or small-scale solar thermal energy units.

1. A process for producing a concentrator, the process comprising:
(a) coating a first side of a first polymer layer with a a metal mirror layer structure comprising a metal mirror layer by physical vapour deposition;
(b) applying a second polymer layer on on an opposite side of the metal mirror layer structure, to obtain a laminate; and
(c) cold curving the laminate, to obtain a self-supporting concentrator,
wherein one of the two polymer layers is highly transparent and faces a solar light source and the other is a backing layer and faces away from the solar light source.

2. The process of claim 1, wherein, prior to (a), the first side of the first polymer layer comprises a highly transparent primer layer.

3. The process of claim 1, wherein a side of the metal mirror layer in the metal mirror structure facing away from the highly transparent polymer layer comprises a metallic protective layer.

4. The process of claim 1, comprising:
coating the backing polymer layer with the metal mirror layer by physical vapour deposition; and then,
optionally, coating an opposite side of the metal mirror layer with a primer and a highly transparent polymer.

5. The process of claim 1, wherein metal mirror layer structure comprises a reflection enhancement stack layer.

6. The process of claim 1, wherein wherein the metal of the mirror layer is silver, gold, or aluminium, and the metal mirror layer has a thickness in a range from 50 to 200 nm.

7. The process of claim 6, the silver mirror layer structure comprises:
optionally a primer layer;
the metal mirror layer; and
optionally an anticorrosion layer obtained by physical vapour deposition.

8. The process of claim 1, the highly transparent polymer is polycarbonate, polystyrene, a styrene copolymer, a fluoropolymer, or PMMA.

9. The process of claim 8, the highly transparent layer comprises at least one additive selected from the group consisting of an inhibitor and a UV stabilizer.

10. The process of claim 8, the highly transparent polymer layer is a multilayer of polymer layers and
wherein the at least one additive is is homogenously present in the layers of the multilayer, present separately from one another between one or more the layers in the multilayer, or a combination thereof.

11. The process of claim 10, wherein a polymer layer of the multilayer is a PMMA-comprising layer.

12. The process of claim 1, the highly transparent layer comprises at least one selected from the group consisting of a scratch-resistant coating and an antisoil coating.

13. The process of claim 1, wherein the polymer of the backing layer is polycarbonate, polystyrene, a styrene copolymer, a polyester, or PMMA.

14. The process of claim 1, wherein adhesive layers are optionally present between each layer of the laminate.

15. The process of claim 1, self-supporting, and may be simultaneously converted to the final form by cold shaping.

16. The process of claim 1, wherein the concentrator has a total thickness in a range from 1 mm to 2 cm.

17. A concentrator, comprising, viewed from a light source:
a polymer layer comprising UV stabilizer, an inhibitor inhibitors, and PMMA;
a silver mirror layer structure having a thickness in a range from 80 and 200 nm;
a backing layer;
wherein a final form of the concentrator is obtained by cold forming.

18. The concentrator of claim 17, further comprising a surface finish layer having a soil-repellent and a scratch resistance-improving property, and an optional first and second adhesive layer,
wherein the concentrator has a structure comprising, viewed from the light source:
(i) the surface finish layer;
(ii) the polymer layer,
(iii) the optional first adhesive layer,
(iv) the silver mirror layer structure comprising
(a) a primer layer,
(b) a silver layer having a thickness in a range from 80 and 130 nm, and
(c) an anticorrosion layer comprising copper or nickel-chromium and having a thickness in a range from 25 and 50 nm;
(v) the optional second adhesive layer; and
(vi) the polymeric backing layer, wherein the polymeric backing layer comprises PMMA, and
wherein a final form of the concentrator is obtained by cold forming.

19. The concentrator of claim 17, in the form of a parabolic trough in a parabolic trough collector.

20. The concentrator of claim 17, in the form of a Fresnel mirror collector, a heliostat reflector, or a solar dish concentrator unit.

21. 17 or 18 in A solar thermal energy unit, comprising the concentrator of claim 17,
wherein the concentrator is in a curved form and the thermal energy unit is medium-scale or small-scale.

22. A concentrated photovoltaic, comprising the concentrator of claim 17, wherein the concentrator is in paraboloid form.
